(19) United States
(12) Patent Application Publication
(10) Pub. No.: US 2016/0027867 A1
(43) Pub. Date: Jan. 28, 2016

(54) SEMICONDUCTOR DEVICE

(71) Applicant: KABUSHIKI KAISHA TOSHIBA, Tokyo (JP)

(72) Inventor: Kenichi MATSUSHITA, Nonoichi Ishikawa (JP)

(21) Appl. No.: 14/634,370

(22) Filed: Feb. 27, 2015

(30) Foreign Application Priority Data
Jul. 25, 2014 (JP) 2014-151648

(51) Int. Cl. H01L 29/06; H01L 21/322; H01L 21/265; H01L 29/868; H01L 29/739

(52) U.S. Cl. CPC H01L 29/0619; H01L 29/868; H01L 29/7393; H01L 21/26506; H01L 21/3221

(57) ABSTRACT

A semiconductor device includes a semiconductor layer having a first p-type semiconductor region at a first surface and a first n-type semiconductor region at a second surface opposite the first. A second n-type semiconductor region having a n-type dopant concentration lower than the first n-type semiconductor region is between the first p-type and first n-type semiconductor regions. A third n-type semiconductor region is disposed between the second n-type semiconductor region and the first p-type semiconductor region. a fourth n-type semiconductor region is disposed between the first n-type semiconductor region and the second n-type semiconductor region. The fourth n-type semiconductor region has a stored carrier lifetime longer than the third n-type semiconductor region and a crystal lattice defect level is higher in the third n-type semiconductor than in the fourth n-type semiconductor region. An anode is disposed on the first surface and a cathode is disposed on the second surface.

### CROSS-REFERENCE TO RELATED APPLICATION

This application is based upon and claims the benefit of priority from Japanese Patent Application No. 2014-151648, filed Jul. 25, 2014, the entire contents of which are incorporated herein by reference.

### FIELD

Embodiments described herein relate to a semiconductor device.

### BACKGROUND

AA PIN diode that employs a pn junction is one example of a power semiconductor device. To reduce switching loss in a PIN diode, a thickness of a drift region in the PIN diode is reduced within a range where a breakdown voltage is not significantly deteriorated. By reducing the thickness of the drift region, an amount of stored carriers at the time of reverse recovery is reduced so that switching loss may be reduced.

However, when an amount of stored carriers stored on a cathode side at the time of reverse recovery becomes extremely small, the carriers easily disappear during the reverse recovery and hence, there exists a possibility that an electric current or a voltage oscillates.

### DESCRIPTION OF THE DRAWINGS

FIG. 1 is a schematic cross-sectional view of a semiconductor device according to a first embodiment.

FIG. 2 is a schematic plan view of the semiconductor device according to the first embodiment.

FIG. 3 is a schematic cross-sectional view depicting a step in a method of manufacturing the semiconductor device according to the first embodiment.

FIG. 4 is a schematic cross-sectional depicting another step in the method of manufacturing the semiconductor device according to the first embodiment.

FIG. 5 is a schematic cross-sectional view of a semiconductor device according to a second embodiment.

### DETAILED DESCRIPTION

According to an embodiment, there is provided a semiconductor device having a reduced oscillation in an electric current or a voltage.

In general, according to one embodiment, a semiconductor device includes a semiconductor layer that has a first surface and a second surface opposite the first surface. A first p-type semiconductor region is formed in the semiconductor layer at the first surface of the semiconductor layer. A first n-type semiconductor region is formed on the second surface of the semiconductor layer. A second n-type semiconductor region is formed in the semiconductor layer between the first p-type semiconductor region and the first n-type semiconductor region. The second n-type semiconductor region has a concentration of n-type dopant that is lower than a concentration of n-type dopant in the first n-type semiconductor region. A third n-type semiconductor region is formed in the semiconductor layer between the first p-type semiconductor region and the second n-type semiconductor region. The third n-type semiconductor region has a concentration of n-type dopant lower than the concentration of n-type dopant in the second n-type semiconductor region. A fourth n-type semiconductor region is formed in the semiconductor layer between the first n-type semiconductor region and the second n-type semiconductor region. The fourth n-type semiconductor region has a concentration of n-type dopant that is lower than the concentration of n-type dopant in the second n-type semiconductor region. In general, the fourth n-type semiconductor layer has a lifetime of stored carriers that is longer than a lifetime of stored carriers in the third n-type semiconductor region. A concentration level (amount) of crystal lattice defects is different in the third and fourth n-type semiconductor regions. An anode is disposed on the first surface of the semiconductor layer and electrically connected to the first p-type semiconductor region. And a cathode is disposed on the second surface of the semiconductor layer and electrically connected to the first n-type semiconductor region.

Hereinafter, exemplary embodiments are explained with reference to drawings. In the explanation made hereinafter, substantially similar parts are given the same reference symbols, and the explanation of such parts is omitted when appropriate after initial explanation.

In this disclosure, the descriptions of “n⁺-type”, “n-type”, and “n⁻-type” mean that a relative concentration of n-type dopant descends in this order. In the same manner, the descriptions of “p⁺-type”, “p-type”, “p⁻-type” mean that a relative concentration of p-type dopant descends in this order.

### First Embodiment

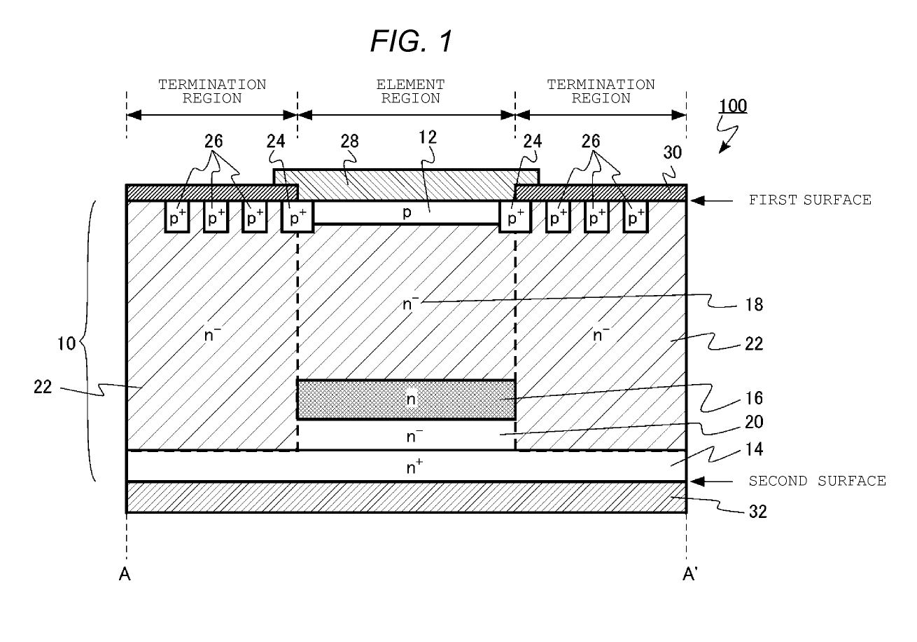

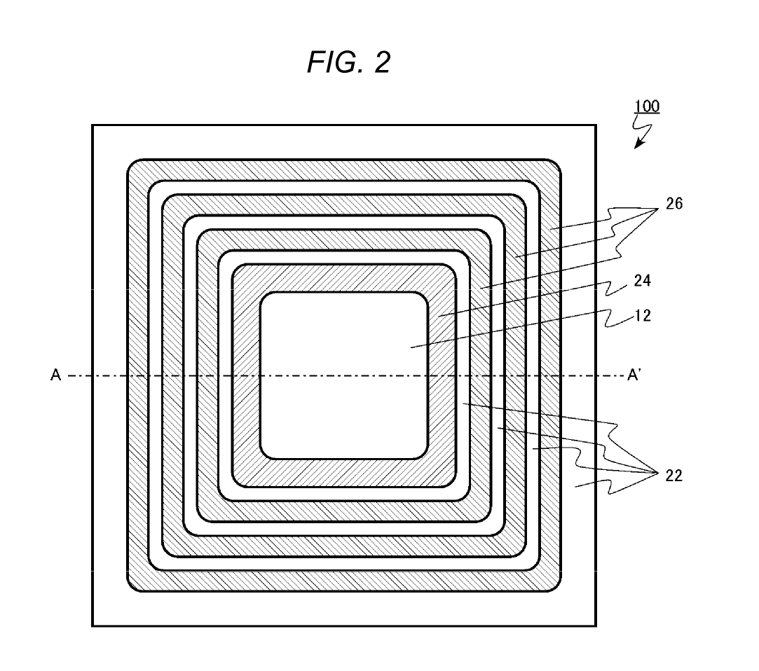

FIG. 1 is a schematic cross-sectional view of the semiconductor device according to this first embodiment. FIG. 2 is a schematic plan view of the semiconductor device according to this first embodiment. FIG. 1 is a schematic cross-sectional view taken along a line A-A′ in FIG. 2.

The semiconductor device according to this embodiment is a PIN diode where an anode and a cathode are disposed with a semiconductor material interposed therebetween. The PIN diode 100 according to this first embodiment includes an element region and a termination region which surrounds the element region. When the PIN diode 100 is in an ON state electric current mainly flows in the element region. The termination region improves device breakdown voltage by alleviating an electric potential at an end portion of the element region when the PIN diode 100 is in an OFF state.

As shown in FIG. 1, the PIN diode 100 according to this embodiment includes a semiconductor layer 10 having a first surface and a second surface disposed on a side opposite to the first surface. The semiconductor layer 10 may be a semiconductor substrate that is made of single crystal silicon, for example. A film thickness of the semiconductor layer 10 is 50 μm or more and 300 μm or less, for example.

An anode region 12 (first p-type semiconductor region) having a p-type conductivity is formed on a first surface side of the semiconductor substrate 10. The anode region 12 is selectively formed on a surface of the element region of the semiconductor substrate 10. The anode region 12 contains, for example, boron (B) as a p-type dopant. A concentration of p-type dopant in anode region 12 is, for example, 1×10¹⁹ cm⁻³ or more and 1×10²¹ cm⁻³ or less.

A cathode region 14 (first n-type semiconductor region) having n⁺-type conductivity is formed on a second surface side of the semiconductor layer 10. The cathode region 14 contains, for example, phosphorus (P) or arsenic (As) as an n-type dopant. A concentration of n-type dopant in cathode region 14 is, for example, 5×10¹⁹ cm⁻³ or more and 1×10²² cm⁻³ or less.

A buffer region 16 (second n-type semiconductor region) having an n-type conductivity is formed in the semiconductor layer 10 between the anode region 12 and the cathode region 14. The buffer region 16 suppresses the extension of a depletion layer when the PIN diode 100 is in an OFF state.

A concentration of n-type dopant in the buffer region 16 is lower than the concentration of n-type dopant in the cathode region 14, consequently the specific resistance of the buffer region 16 is higher than the specific resistance of the cathode region 14.

The buffer region 16 contains, for example, hydrogen (H) or helium (He) as an n-type dopant. The buffer region 16 may further contain phosphorus (P) or arsenic (As) as an n-type dopant. A concentration of hydrogen (H) or helium (He) in the buffer region 16 is, for example, 1×10¹⁶ cm⁻³or more and 1×10¹⁹ cm⁻³ or less.

A drift region 18 (third n-type semiconductor region) having n⁻-type conductivity is formed in the semiconductor layer 10 between the anode region 12 and the buffer region 16. A concentration of n-type dopant in the drift region 18 is lower than the concentration of n-type dopant in the buffer region 16, consequently the specific resistance of the drift region 18 is higher than the specific resistance of the buffer region 16.

The drift region 18 contains, for example, phosphorus (P) or arsenic (As) as an n-type dopant. A concentration of n-type dopant in the drift region 18 is, for example, 1×10¹⁵ cm⁻³ or more and 5×10¹⁶ cm⁻³ or less.

A carrier storage region 20 (fourth n-type semiconductor region) having n⁻-type conductivity is formed in the semiconductor layer 10 between the cathode region 14 and the buffer region 16. A concentration of n-type dopant in the carrier storage region 20 is lower than the concentration of n-type dopant in the buffer region 16, consequently the specific resistance of the carrier storage region 20 is higher than the specific resistance of the buffer region 16.

The carrier storage region 20 contains, for example, phosphorus (P) or arsenic (As) as an n-type dopant. A concentration of n-type dopant in the carrier storage region 20 is, for example, 1×10¹⁵ cm⁻³ or more and 5×10¹⁶ cm⁻³ or less. The concentration of n-type dopant in the carrier storage region 20 is substantially equal to the concentration of n-type dopant in the drift region 18.

The lifetime of carriers in the carrier storage region 20 is longer than the lifetime of carriers in the drift region 18. The carrier storage region 20 suppresses the oscillation of the PIN diode 100 during reverse recovery by storing carriers in the carrier storage region 20.

The relationship between the lifetime of carriers in the drift region 18 and the lifetime of carriers in the carrier storage region 20 may be determined by, for example, evaluating a specimen prepared by obliquely grinding (beveling) the semiconductor layer 10 using Spreading Resistance Analysis (SRA), which is also referred to as Spreading Resistance Profiling (SRP) to profile resistivity (which is related to stored carrier concentration) versus depth.

The element region includes the anode region 12, the drift region 18, the buffer region 16, the carrier storage region 20, and the cathode region 14.

In the element region, the concentration distribution of hydrogen or helium in the direction perpendicular to the first surface has a peak in the buffer region (second n-type semiconductor region) 16. The position of the peak of the concentration distribution of hydrogen or helium is disposed within a range from 20 μm or more to 30 μm or less from the second surface, for example. A full-width at half maximum (FWHM) of the peak of hydrogen or helium is 10 μm or more and 50 μm or less, for example.

It is desirable that a thickness of the drift region (third n-type semiconductor region) 18 in the direction orthogonal to the first surface be larger than a thickness of the carrier storage region (fourth n-type semiconductor region) 20 in the direction orthogonal to the first surface. In other words, it is desirable that the buffer region 16 be formed in the semiconductor layer 10 at a position closer to the cathode region 14 side than the anode region 12 is. Due to such a configuration, it is possible to achieve both suppression of the oscillation of an electric current or a voltage during reverse recovery and the improvement (increase) in breakdown voltage.

An peripheral region 22 (fifth n-type semiconductor region) having n type conductivity is formed in the semiconductor layer 10 so as to surround the anode region 12, the drift region 18, the buffer region 16, and the carrier storage region 20. A concentration of n-type dopant in the peripheral region 22 is lower than the concentration of n-type dopant in the buffer region 16. The peripheral region 22 contains, for example, phosphorus (P) or arsenic (As) as an n-type dopant. A concentration of n-type dopant in peripheral region 22 is, for example, 1×10¹⁵ cm⁻³ or more and 5×10¹⁶ cm⁻³ or less. The concentration of n-type dopant in the peripheral region 22 is substantially equal to the concentration of n-type dopant in the drift region 18.

The lifetime of carriers in the peripheral region 22 is shorter than the lifetime of carriers in the carrier storage region 20. The lifetime of carriers in the peripheral region 22 is substantially equal to the lifetime of carriers in the drift region 18.

A first guard ring 24 of p⁺-type conductivity is formed on a first surface side of the semiconductor layer 10 so as to surround the p-type anode region (first p-type semiconductor region) 12. The first guard ring 24 is formed so as to be in contact with the anode region 12. A concentration of p-type dopant in the first guard ring 24 is higher than the concentration of p-type dopant in the anode region 12, for example. The first guard ring 24 contains, for example, boron (B) as a p-type dopant. The concentration of p-type dopant in the first guard ring 24 is, for example, 5×10¹⁹ cm⁻³ or more and 3×10²¹ cm⁻³ or less. A depth of the first guard ring 24 is, for example, larger than a depth of the anode region 12.

Second guard ring 26 (second p-type semiconductor region) of p⁺-type conductivity are formed on the first surface side of the semiconductor layer 10 so as to surround the p-type anode region 12 (first p-type semiconductor region). The second guard rings 26 are formed such that the peripheral region 22 (fifth n-type semiconductor region) is interposed between the p-type anode region 12 and the first guard ring 24. A concentration of p-type dopant in the second guard rings 26 is higher than the concentration of p-type dopant in the anode region 12, for example. The second guard rings 26 contain, for example, boron (B) as a p-type dopant. The concentration of p-type dopant in the second guard rings 26 is, for example, 5×10¹⁹ cm⁻³ or more and 3×10²¹ cm⁻³ or less. A depth of the second guard rings 26 is greater than the depth of the anode region 12, for example.

The termination region includes the first guard ring 24, the second guard rings 26, the peripheral region 22, and the cathode region 14.

In this first embodiment, the buffer region 16 is formed only in the element region, and is not formed in the termination region. The carrier storage region 20 is also formed only in the element region, and is not formed in the termination region.

It is desirable that the buffer region 16 be formed inside the second guard rings 26. It is desirable that an edge portion of the buffer region 16 be disposed closer to the element region side than to a region corresponding to a projection of the second guard rings 26 toward a second surface side.

The PIN diode 100 includes an anode 28 electrically connected to the anode region (first p-type semiconductor region) 12. The anode 28 is in contact with the anode region 12 through an opening portion formed in an insulation film 30 on the first surface of the semiconductor layer 10.

The PIN diode 100 includes a cathode 32 electrically connected to the cathode region (first n-type semiconductor region) 14. The cathode 32 is in contact with the cathode region 14 on the second surface of the semiconductor layer 10.

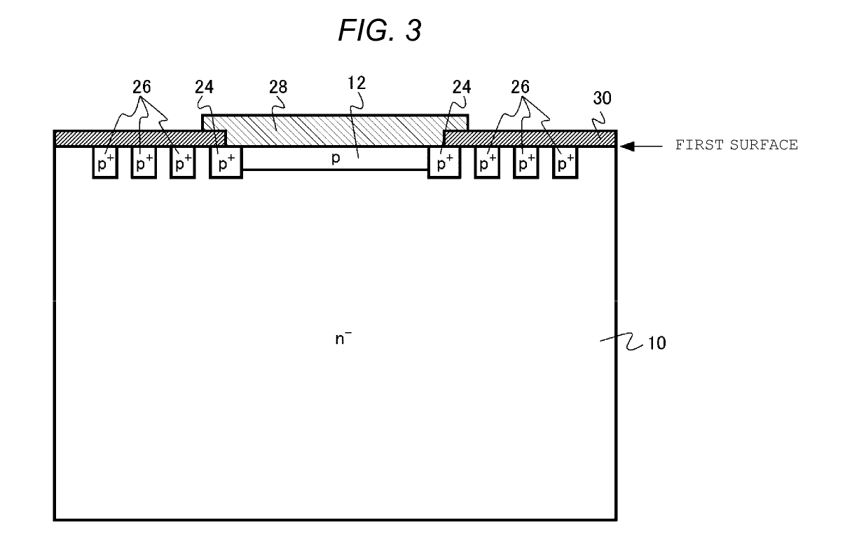

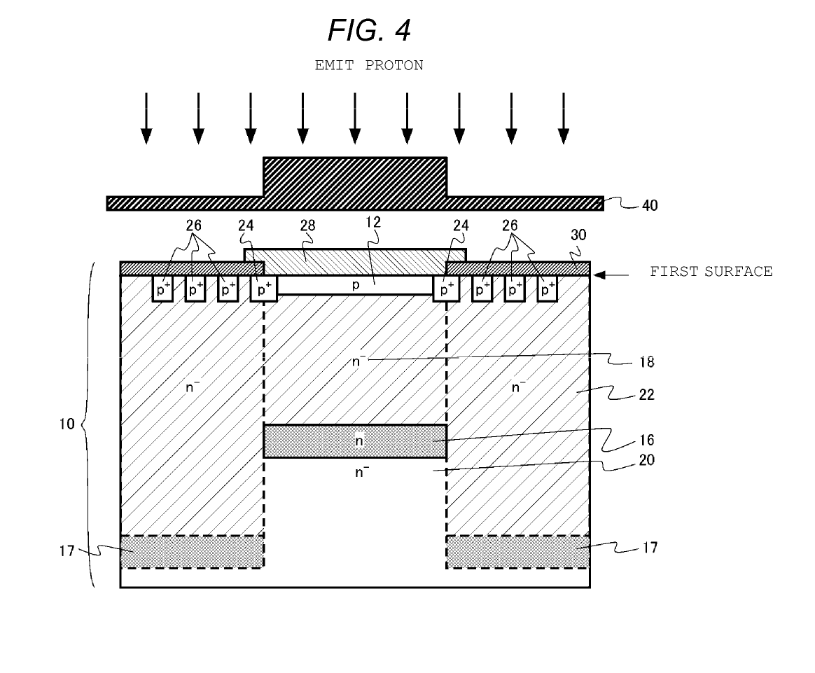

Next, a method of manufacturing a semiconductor device according to this embodiment is explained. FIG. 3 and FIG. 4 are schematic cross-sectional views of a semiconductor device at points in the manufacturing process.

Firstly, an n⁻-type semiconductor layer 10 is prepared. Next, a p-type anode region 12, a first guard ring 24, and second guard rings 26 are formed in the n⁻-type semiconductor layer 10 using a process technique such as a known ion injection method.

Next, an insulation film 30 is formed on the semiconductor layer 10 using a standard process technique. The insulation film 30 comprises a silicon oxide film, for example.

Next, using a standard process technique, an opening portion is formed in the insulation film 30 above the anode region 12, and an anode 28 is formed in the opening portion (FIG. 3). The anode 28 is made of metal.

Next, proton (H⁺) is deposited into the semiconductor layer 10 from a first surface side of the semiconductor layer (FIG. 4). Helium ion (He²⁺) may be deposited into the semiconductor layer 10 in place of proton (H⁺). Protons are emitted for implant/deposition using an accelerator such as a cyclotron or a Van de Graaff accelerator, for example.

In depositing protons into the semiconductor layer 10, a thickness of a mask 40 is set such that the thickness of the mask 40 at a portion corresponding to an element region is large, and the thickness of the mask 40 at a portion corresponding to a termination region is small. By changing the thickness of the mask 40 depending on location, a peak position of the proton distribution is made shallower in the element region than in the termination region. The mask 40 is made of aluminum, lead, gold, or tungsten, for example.

Next, annealing is applied to the semiconductor layer 10, thus activating deposited protons. The annealing is performed in a hydrogen atmosphere or an inert gas atmosphere at a temperature of 400° C. or more and 450° C. or less, for example.

By depositing the protons into the semiconductor layer 10 and by applying annealing the semiconductor layer 10, the element region is formed into the structure which includes a drift region 18 and a buffer region 16, wherein the lifetime of carriers is short, and a carrier storage region 20, wherein the lifetime of carriers is long. On the other hand, the termination region is formed into the structure which includes a peripheral region 22, wherein the lifetime of carriers is short, and a region 17 corresponding to the buffer region 16 of the element region (FIG. 4). The lifetime of carriers in the drift region 18 and the peripheral region 22 is short due to defects caused in the substrate crystal lattice when ions/protons pass into the drift region 18 and the peripheral region 22 remain in these regions even after the annealing is finished. Thus, the concentration level of crystal lattice defects (defectivity level) in the drift region 18 and the peripheral region 22 is generally higher than portions of the semiconductor layer which have had fewer (or no) ions/protons passed therethrough during the ion/proton deposition process.

Next, a rear surface side of the semiconductor layer 10 is ground to reduce a film thickness of the semiconductor layer 10. The semiconductor layer 10 is ground until it has a film thickness such that the region 17 of the termination region (corresponding to the buffer region 16) is eliminated by the grinding process. For example, the film thickness of the semiconductor layer 10 after grinding is 100 μm or less.

Next, by injecting a phosphorus ion or an arsenic ion, for example, into the semiconductor substrate 10, and then activating the phosphorus ion or the arsenic ion by laser annealing, an n⁺-type cathode region 14 is formed. Thereafter, a cathode 32 is formed using a standard process technique. The cathode 32 is formed of a metal.

Through the above-mentioned steps, the PIN diode 100 shown in FIG. 1 and FIG. 2 is formed.

Next, the manner of operation and advantageous effects of the PIN diode according to this first embodiment are explained.

To reduce a switching loss in the PIN diode, it is effective to reduce a total amount of minority carriers by reducing a film thickness of the drift region. However, when an amount of carriers on a cathode side at the time of reverse recovery becomes extremely small, the carriers easily disappear during the reverse recovery and hence, there exists a possibility that the oscillation of an electric current and a voltage occurs.

The PIN diode 100 according to this first embodiment includes the buffer region 16 and the carrier storage region 20 in the element region. The extension of the depletion layer into the drift region 18 may be suppressed by the buffer region 16 having a concentration of n-type dopant higher than a concentration of n-type dopant in the drift region 18.

From a viewpoint of suppressing an electric field strength in the depletion layer, it is desirable that the distribution of n-type dopant in the buffer region 16 be diffuse/widen to some extent. Accordingly, it is desirable that a full-width at half maximum (FWHM) of a peak of hydrogen or helium ions in the buffer region 16 be 10 μm or more and 50 μm or less, for example.

Positive holes (holes) are stored in the carrier storage region 20, where the lifetime of minority carriers is long. Accordingly, at the time of reverse recovery, a change in electric current is gentle due to the presence of positive holes stored in the carrier storage region 20. Accordingly, the oscillation of an electric current and a voltage at the time of reverse recovery may be suppressed.

From a viewpoint of allowing the carrier storage region 20 to have a sufficient thickness and allowing the sufficient positive holes to be stored in the carrier storage region 20, it is desirable that the position of the peak of hydrogen or helium ions in the buffer region 16 be disposed at a position away from the second surface by 20 μm or more and 30 μm or less.

In PIN diode 100, the extension of the depletion layer may be suppressed and, at the same time, the oscillation of an electric current and a voltage at the time of reverse recovery may be suppressed. Accordingly, it is possible to provide a PIN diode where a switching loss is reduced by reducing a thickness of the drift region and, at the same time, the oscillation of an electric current and a voltage at the time of reverse recovery may be suppressed.

In the PIN diode 100 according to this first embodiment, the lifetime of minority carriers is shorter in the drift region 18 in the element region than in the carrier storage region 20 in the element region. Accordingly, an amount of electric current at the time of reverse recovery may be suppressed and hence, a switching loss may be reduced.

In general, in a PIN diode, even when a guard ring or the like is included with the PIN diode, a breakdown voltage is easily lowered in the termination region where an electric field is concentrated easily, as compared with the element region. Accordingly, for example, when the buffer region 16 is formed in the termination region in the substantially same manner as in the element region, the limit on the reduction of a thickness of the substrate is determined based on the breakdown voltage of the termination region.

In the PIN diode 100, the buffer region 16 for suppressing the extension of the depletion layer is formed only in the element region, and is not formed in the termination region. Accordingly, a breakdown voltage in the termination region is enhanced, as compared to a breakdown voltage in the element region. Accordingly, a thickness of the substrate may be further reduced and hence, a switching loss may be further reduced.

From a viewpoint of enhancing the breakdown voltage in the termination region, it is desirable that the buffer region 16 be formed inside the second guard rings 26. In other words, it is desirable that an edge portion of the buffer region 16 be present on an element region side rather than in a region formed by projecting the second guard rings 26 toward a second surface side.

According to the PIN diode 100, by optimizing a concentration profile of the buffer region 16, it is possible to allow an avalanche breakdown to occur at scattered positions in the element region. Accordingly, the switching ruggedness may be further enhanced.

When the lifetime of carriers in the termination region is long, a carrier injection amount from a cathode region 14 side is increased at the time of reverse recovery so that there exists a possibility that a switching ruggedness (recovery ruggedness) at the time of reverse recovery is lowered. In the PIN diode 100 according to this embodiment, the lifetime of carriers is set short in the peripheral regions 22 which are n-type regions in the termination region. Accordingly, it is possible to increase a switching ruggedness at the time of reverse recovery.

According to this first embodiment, it is possible to provide a PIN diode where both the suppression of the oscillation of an electric current and a voltage and the reduction of the switching loss may be achieved. Simultaneously, it is also possible to enhance a switching ruggedness of the PIN diode.

### Second Embodiment

A semiconductor device according to the second embodiment is substantially equal to the semiconductor device according to the first embodiment except for that a second n-type semiconductor region is divided into a plurality of regions.

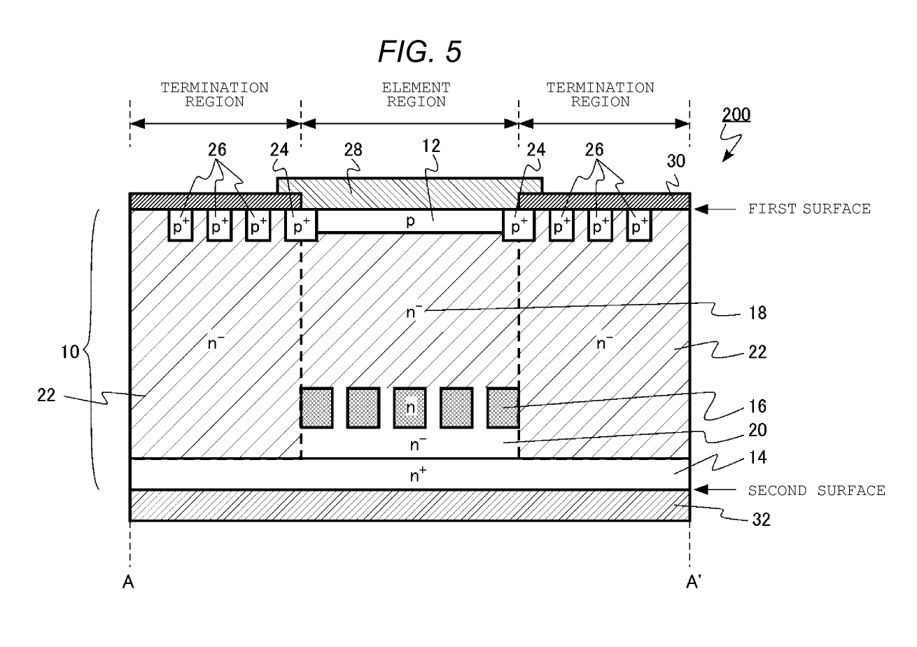

FIG. 5 is a schematic cross-sectional view of the semiconductor device according to this second embodiment.

In a PIN diode 200 according to this second embodiment, a buffer region (second n-type semiconductor region) 16 is divided into a plurality of regions.

In the PIN diode 200, a breakdown voltage becomes the lowest at end portions of respective divided buffer regions in the element region. As a result, an avalanche breakdown occurs at positions corresponding to the end portions of the respective buffer regions. Accordingly, positions where an avalanche breakdown occurs are scattered so that the switching ruggedness is enhanced.

According to this second embodiment, it is possible to provide a PIN diode where both the suppression of the oscillation of an electric current and a voltage and the reduction of the switching loss may be achieved. Simultaneously, it is also possible to further enhance a switching ruggedness of the PIN diode, as compared to the first embodiment.

The explanation has been made by taking single crystal silicon as an example of a material for forming the semiconductor layer in the embodiments heretofore. However, other semiconductor materials such as silicon carbide or gallium nitride, for example, may be used as the semiconductor layer in the present disclosure.

Further, the explanation has been made with respect to a single PIN diode as an example in the embodiments. However, the present disclosure is also applicable to a PIN diode portion of a Reverse Conduction diode-IGBT (RC-IGBT) where an Insulated Gate Bipolar Transistor (IGBT) and a PIN diode are formed together on one chip.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor layer that has a first surface and a second surface opposite the first surface;
a first p-type semiconductor region in the semiconductor layer at the first surface;
a first n-type semiconductor region in the semiconductor layer at the second surface;
a second n-type semiconductor region in the semiconductor layer between the first p-type semiconductor region and the first n-type semiconductor region, the second n-type semiconductor region having a concentration of n-type dopant that is lower than a concentration of n-type dopant in the first n-type semiconductor region;
a third n-type semiconductor region in the semiconductor layer between the first p-type semiconductor region and the second n-type semiconductor region, the third n-type semiconductor region having a concentration of n-type dopant lower than the concentration of n-type dopant in the second n-type semiconductor region;
a fourth n-type semiconductor region in the semiconductor layer between the first n-type semiconductor region and the second n-type semiconductor region, the fourth n-type semiconductor region having a concentration of n-type dopant that is lower than the concentration of n-type dopant in second n-type semiconductor region;
an anode on the first surface and electrically connected to the first p-type semiconductor region; and
a cathode on the second surface and electrically connected to the first n-type semiconductor region, wherein
the third n-type semiconductor region has a concentration level of crystal lattice defects that is higher than a concentration level of crystal lattice defects of the fourth n-type semiconductor region.

2. The semiconductor device according to claim 1, wherein a concentration distribution of hydrogen or helium ions along a direction orthogonal to the first surface has a peak in the second n-type semiconductor region.

3. The semiconductor device according to claim 2, wherein a thickness of the third n-type semiconductor region in a direction orthogonal to the first surface is greater than a thickness of the fourth n-type semiconductor region in the direction orthogonal to the first surface.

4. The semiconductor device according to claim 1, further comprising:
a fifth n-type semiconductor region in the semiconductor layer and encircling the first p-type semiconductor region, the second n-type semiconductor region, the third n-type semiconductor region, and the fourth n-type semiconductor region in a plane parallel to first surface, the fifth n-type semiconductor region having a concentration of n-type dopant that is lower than the concentration of n-type dopant in the second n-type semiconductor region, wherein
the fifth n-type semiconductor region has a concentration level of crystal lattice defects that is higher than the concentration level of crystal lattice defects of the fourth n-type semiconductor region.

5. The semiconductor device according to claim 4, further comprising:
a plurality of second p-type semiconductor regions at the first surface of the semiconductor layer, wherein
the plurality of second p-type semiconductor regions surround the first p-type semiconductor region in the plane parallel to the first surface,
the plurality of second p-type semiconductor regions extend in to the semiconductor layer in a direction orthogonal to the first surface for a distance that is greater than a distance the first p-type semiconductor region extends into the semiconductor layer in the direction orthogonal to the first surface; and
portions of the fifth n-type semiconductor region are between the plurality of second p-type semiconductor regions and the first p-type semiconductor region.

6. The semiconductor device according to claim 5, further comprising:
a first guard ring region of p-type conductivity at the first surface of the semiconductor layer and directly adjacent the first p-type semiconductor region, the first guard ring region surrounding the first p-type semiconductor region in the plane parallel to the first surface and being between the first p-type semiconductor region and the plurality of second p-type semiconductor regions.

7. The semiconductor device according to claim 1, wherein a thickness of the third n-type semiconductor region in a direction orthogonal to the first surface is greater than a thickness of the fourth n-type semiconductor region in the direction orthogonal to the first surface.

8. The semiconductor device according to claim 1, wherein the semiconductor layer has an insulated gate bipolar transistor (IGBT) formed therein.

9. The semiconductor device according to claim 1, wherein the second n-type semiconductor region includes a plurality of n-type semiconductor sub-portions spaced apart from each other in the direction parallel to the first surface, a portion of the fourth n-type semiconductor region being between adjacent sub-portions of the plurality of n-type semiconductor sub-portions.

10. A semiconductor device, comprising:
a semiconductor layer that has a first surface and a second surface opposite the first surface;
a first p-type semiconductor region in the semiconductor layer at the first surface;
a first n-type semiconductor region in the semiconductor layer at the second surface;
a second n-type semiconductor region in the semiconductor layer between the first p-type semiconductor region and the first n-type semiconductor region, the second n-type semiconductor region having a concentration of n-type dopant that is lower than a concentration of n-type dopant in the first n-type semiconductor region;
a third n-type semiconductor region in the semiconductor layer between the first p-type semiconductor region and the second n-type semiconductor region, the third n-type semiconductor region having a concentration of n-type dopant lower than the concentration of n-type dopant in the second n-type semiconductor region; and
a fourth n-type semiconductor region in the semiconductor layer between the first n-type semiconductor region and the second n-type semiconductor region, the fourth n-type semiconductor region having a concentration of n-type dopant that is lower than the concentration of n-type dopant in second n-type semiconductor region, wherein
the third n-type semiconductor region has a concentration level of crystal lattice defects that is higher than a concentration level of crystal lattice defects of the fourth n-type semiconductor region.

11. The semiconductor device according to claim 10, further comprising:
a second p-type semiconductor region at the first surface of the semiconductor layer and surrounding the first p-type semiconductor region in a plane parallel to the first surface, the second p-type semiconductor region being spaced apart from the first p-type semiconductor region by a portion of a fifth n-type semiconductor region in the semiconductor layer, the fifth n-type semiconductor region encircling the first p-type semiconductor region, the second n-type semiconductor region, the third n-type semiconductor region, and the fourth n-type semiconductor region in the plane parallel to first surface, the fifth n-type semiconductor region having a concentration of n-type dopant that is lower than the concentration of n-type dopant in the second n-type semiconductor region, wherein
the fifth n-type semiconductor region has a concentration level of crystal lattice defects that is higher than the concentration level of crystal lattice defects of the fourth n-type semiconductor region.

12. The semiconductor device according to claim 11, wherein a concentration distribution of hydrogen or helium ions along a direction orthogonal to the first surface has a peak in the second n-type semiconductor region.

13. The semiconductor device according to claim 12, further comprising:
an anode on the first surface and electrically connected to the first p-type semiconductor region; and
a cathode on the second surface and electrically connected to the first n-type semiconductor region.

14. The semiconductor device according to claim 11, wherein the second n-type semiconductor region includes a plurality of n-type semiconductor sub-portions spaced apart from each other in the direction parallel to the first surface, a portion of the fourth n-type semiconductor region being between adjacent sub-portions of the plurality of n-type semiconductor sub-portions.

15. A method of manufacturing a semiconductor device, comprising:
forming a first p-type semiconductor region at a first surface of a semiconductor layer, the semiconductor layer having a second surface opposite the first surface and a n-type conductivity;
forming a second n-type semiconductor region in the semiconductor layer between the first p-type semiconductor region and the second surface by implanting ions through the first surface into the semiconductor layer, the ions being at least one of hydrogen ions and helium ions, the second n-type semiconductor region being spaced apart from the second surface by a first portion of the semiconductor layer and spaced apart from the first p-type semiconductor region by a second portion of the semiconductor layer;
grinding the second surface of the semiconductor layer to reduce a thickness of the semiconductor layer without removing the second n-type semiconductor region;
after grinding the second surface of the semiconductor layer, forming a first n-type semiconductor region at the second surface of the semiconductor layer having a concentration of n-type dopant that is higher than a concentration of n-type dopant in the second n-type semiconductor region, the first and second n-type semiconductor regions being spaced apart by the first portion of the semiconductor layer, which has a concentration level of crystal lattice defects that is lower than a concentration level crystal lattice defects of the second portion of the semiconductor layer.

16. The method of manufacturing a semiconductor device according to claim 15, further comprising:
forming an anode on the first surface, the anode being electrically connected to the first p-type semiconductor layer; and
forming a cathode on the second surface, the cathode being electrically connected to the first n-type semiconductor layer.

17. The method of manufacturing a semiconductor device according to claim 15, wherein implanted ions are hydrogen ions.

18. The method of manufacturing a semiconductor device according to claim 15, further comprising:
forming a second p-type semiconductor region at the first surface of the semiconductor layer, the second p-type semiconductor region surrounding the first p-type semiconductor region in a plane parallel to the first surface, the second p-type region being spaced apart from the first p-type semiconductor region.

19. The method of manufacturing a semiconductor device according to the claim 15, wherein ions are implanted with a peak concentration in the semiconductor layer at a distance closer to the second surface than to the first surface.

20. The method of manufacturing a semiconductor device according to the claim 15, wherein the second n-type semiconductor region includes a plurality of n-type semiconductor sub-portions spaced apart from each other in a direction parallel to the first surface.
